(19) United States
(12) Patent Application Publication
(10) Pub. No.: US 2015/0211119 A1
(43) Pub. Date: Jul. 30, 2015

(54) FILM DEPOSITION APPARATUS

(71) Applicant: Tokyo Electron Limited, Tokyo (JP)

(72) Inventors: Yuji ONO, Iwate (JP); Mitsuhiro TACHIBANA, Yamanashi (JP); Manabu HONMA, Iwate (JP)

(21) Appl. No.: 14/604,827

(22) Filed: Jan. 26, 2015

(30) Foreign Application Priority Data
Jan. 29, 2014 (JP) 2014-014575

(51) Int. Cl. C23C 16/455; C23C 16/24; C23C 16/458; C23C 16/46

(52) U.S. Cl. CPC C23C 16/45565; C23C 16/463; C23C 16/24; C23C 16/4584

(57) ABSTRACT

A film deposition apparatus includes a vacuum chamber, and a turntable having a substrate receiving area provided in the vacuum chamber. A heating unit is provided to heat the turntable so as to heat the substrate up to 600 degrees C. or higher. A process gas supply part is provided to supply a process gas having a decomposition temperature of 520 degrees C. or lower under 1 atmospheric pressure or lower, to the substrate. A gas shower head is provided in the process gas supply part and has a plurality of gas discharge holes provided in an opposed part facing a passing area of the substrate placed on the turntable. A cooling mechanism is provided in the process gas supply part and is configured to cool the opposed part in the gas shower head up to a temperature lower than the decomposition temperature of the process gas.

### CROSS-REFERENCE TO RELATED APPLICATIONS

This patent application is based upon and claims the benefit of priority of Japanese Patent Application No. 2014-14575, filed on Jan. 29, 2014, the entire contents of which are incorporated herein by reference.

### BACKGROUND OF THE INVENTION

1. Field of the Invention

The present invention relates to a film deposition apparatus for obtaining a thin film by supplying a process gas to a substrate.

2. Description of the Related Art

A film deposition apparatus that performs an ALD (Atomic Layer Deposition) method is, for example, known as an apparatus and a method to deposit a thin film such as a silicon oxide (SiO₂) film on a substrate such as a semiconductor wafer (which is hereinafter called a “wafer”). The film deposition apparatus includes a horizontal turntable in a process chamber that is evacuated and made a vacuum atmosphere, and the turntable includes a plurality of concave portions in which a wafer is accommodated in a circumferential direction of the turntable. A plurality of gas nozzles is arranged so as to face the turntable. The plurality of gas nozzles includes reaction gas nozzles for forming processing atmospheres by supplying process gases (reaction gases), and separation gas nozzles for supplying a separation gas that separates the processing atmospheres from each other above the turntable. The reaction gas nozzles and the separation gas nozzles are alternately arranged above the turntable in the process chamber. One of the reaction gas nozzles supplies, for example, BTBAS (bis-(tertiary butyl amino)-silane) gas as a source gas of the silicon oxide film. Such a film deposition apparatus is disclosed in Japanese Laid-Open Patent Application Publication No. 2011-100956.

As disclosed in Japanese Laid-Open Patent Application Publication No. 2011-100956, the reaction gas nozzles have gas discharge holes arranged in a row from a central side to a peripheral side. However, in such a structure, because a period when the wafer contacts the reaction gas is relatively short, it is difficult to increase a film deposition speed by enhancing the adsorption efficiency of the reaction gas to the wafer.

Moreover, in order to improve a film quality by annealing a film deposited on a surface of the wafer while depositing the film, there is a demand for making a temperature of the turntable during the film deposition higher than a conventional temperature, that is to say, a temperature equal to or higher than 600 degrees C. However, when the temperature of the turntable is made higher in such a manner, surface temperatures of the reaction gas nozzles increase due to radiation heat from the turntable. This causes BTBAS gas discharged from the reaction gas nozzles to decompose before adsorbing on the wafer, and the decomposed matter adheres to the reaction gas nozzles without adhering to the wafer.

Although Japanese Laid-Open Patent Application Publication No. 2001-254181 discloses that a gas shower head supplies a variety of gases to a substrate, but does not disclose the above-mentioned problem and a method of solving the problem. Japanese Laid-Open Patent Application Publication No. 2011-100956 does not also disclose the above-mentioned problem and a method of solving the problem.

### SUMMARY OF THE INVENTION

Embodiments of the present invention provide a film deposition apparatus solving one or more of the problems discussed above.

More specifically, the embodiments of the present invention may provide a film deposition apparatus that increases a film deposition speed on a substrate and can enhances a film quality.

According to one embodiment of the present invention, there is provided a vacuum processing apparatus for obtaining a thin film by supplying a process gas to a substrate. The film deposition apparatus includes a vacuum chamber, and a rotatable turntable provided in the vacuum chamber and having a substrate receiving area provided in a surface therein to receive a substrate thereon. The film deposition apparatus further includes a heating unit configured to heat the turntable so as to heat the substrate up to 600 degrees C. or higher in order to perform a film deposition process on the substrate, and a process gas supply part configured to supply a process gas having a decomposition temperature equal to or higher than 520 degrees C. under 1 atmospheric pressure or lower, to the substrate. A gas shower head is provided in the process gas supply part and has a plurality of gas discharge holes provided in an opposed part facing a passing area of the substrate placed on the turntable. A cooling mechanism is provided in the process gas supply part and is configured to cool the opposed part in the gas shower head up to a temperature lower than the decomposition temperature of the process gas.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional view of a film deposition apparatus according to an embodiment of the present invention;

FIG. 2 is a perspective view illustrating a schematic inner configuration of the film deposition apparatus;

FIG. 3 is a horizontal section plan view illustrating the film deposition apparatus;

FIG. 4 is a vertical cross-sectional side view cut along a circumferential direction of a vacuum chamber of the film deposition apparatus;

FIG. 5 is an explanation drawing illustrating an example of a layout of a pipe arrangement for a coolant provided in a gas shower head of the film deposition apparatus;

FIG. 6 is a first explanation drawing illustrating an example of a layout of gas discharge holes in a lower surface of the gas shower head;

FIG. 7 is a vertical cross-sectional side view of the vacuum chamber for illustrating gas flows formed during a film deposition process;

FIG. 8 is a horizontal cross section plan view of the vacuum chamber for illustrating gas flows formed during the film deposition process;

FIG. 9 is a horizontal cross section plan view of the vacuum chamber for illustrating gas flows formed during a cleaning treatment;

FIG. 10 is a second explanation drawing illustrating another example a layout of the gas discharge holes in the lower surface of the gas shower head;

FIG. 11 is a third explanation drawing illustrating still another example a layout of the gas discharge holes in the lower surface of the gas shower head; and

FIG. 12 is a fourth explanation drawing illustrating still another example a layout of the gas discharge holes in the lower surface of the gas shower head.

### DETAILED DESCRIPTION OF THE PREFERRED EMBODIMENTS

A description is given below of embodiments of the present invention, with reference to accompanying drawings.

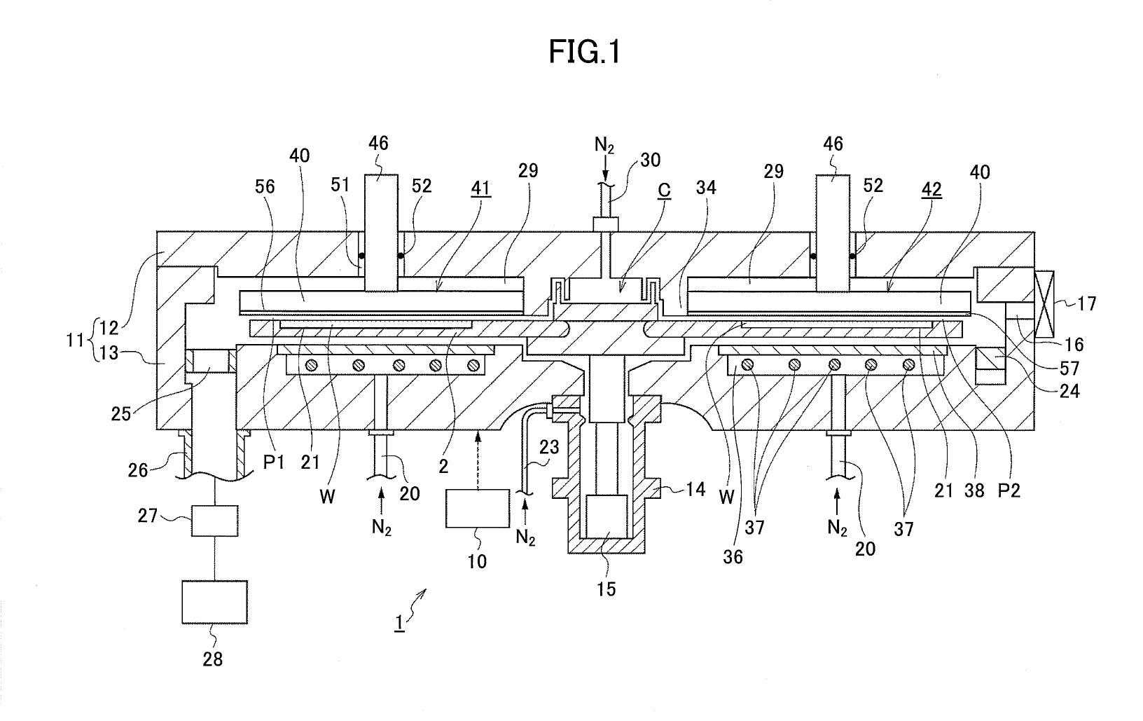

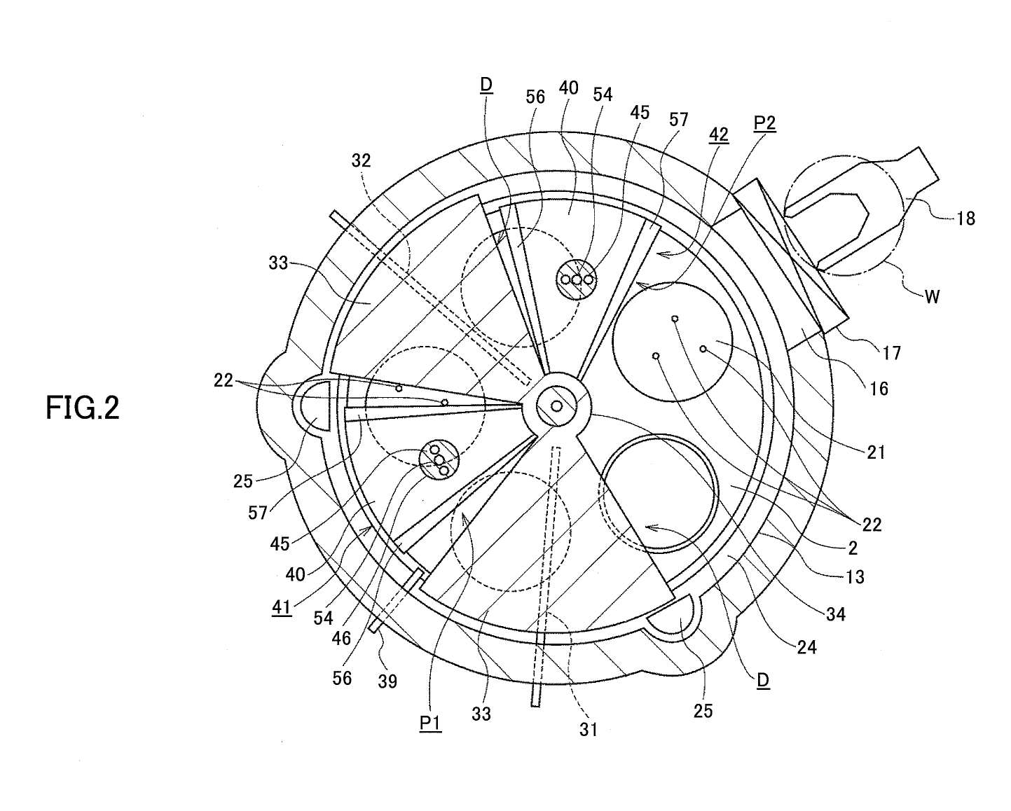

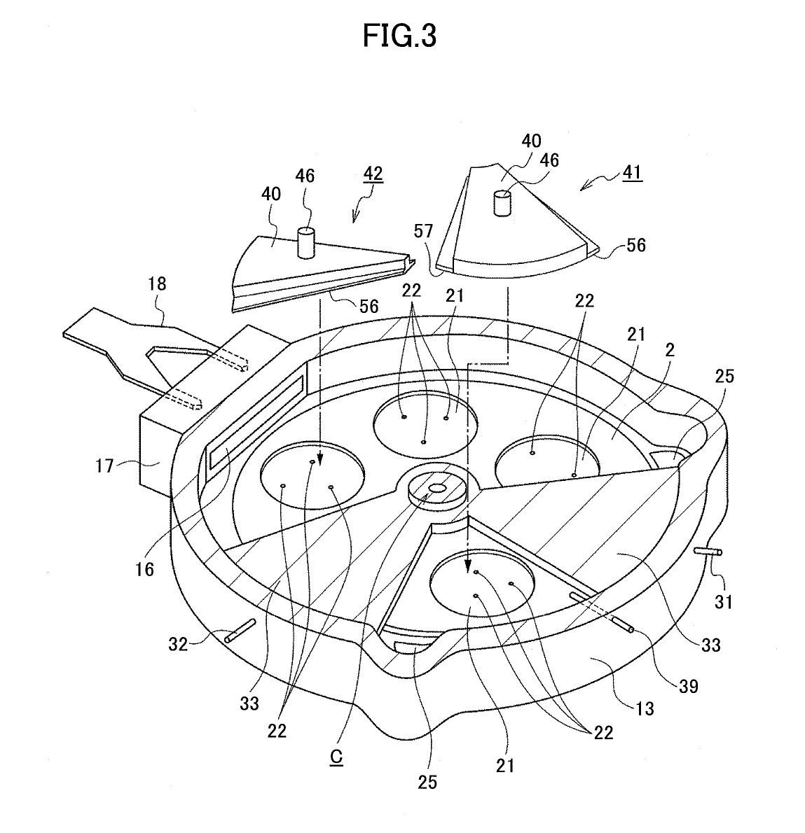

To begin with, a description is given below of a film deposition apparatus 1 for performing ALD on a wafer W that is a substrate according to an embodiment of the present invention, with reference to FIGS. 1 through 3. FIG. 1 is a vertical cross-sectional view of the film deposition apparatus 1, and FIG. 2 is a schematic perspective view illustrating the inside of the film deposition apparatus 1. FIG. 3 is a horizontal section plan view of the film deposition apparatus 1. The film deposition apparatus 1 includes a flattened vacuum chamber (process chamber) 11 having an approximately round planar shape, and a disk-shaped horizontal turntable 2 provided in the vacuum chamber 11. The vacuum chamber 11 is constituted of a ceiling plate 12 and a chamber body 13 that forms a side wall and a bottom of the vacuum chamber 11. As illustrated in FIG. 1, a cover 14 that covers a central part on the underside of the chamber body 13 is provided.

The turntable 2 is connected to a rotary drive mechanism 15, and rotates around a central axis thereof in a circumferential direction by the rotary drive mechanism 15. Five circular concave portions 21 are formed in a surface on the upper surface side (one surface side) of the turntable 2 in a rotational direction thereof, and the wafers W that are substrates are placed on bottom surfaces 21a of the concave portions 21. More specifically, the concave portions 21 constitute receiving areas of the wafers W. The wafers W accommodated in the concave portions 21 rotate around the central axis of the turntable 2 by the rotation of the turntable 2. Three through holes 22 that penetrate through the turntable 2 in a thickness direction are formed in the bottom surface 21a of each of the concave portions 21.

A transfer opening 16 is opened in a side wall of the vacuum chamber 11, and is configured to be openable and closeable by a gate valve 17. A wafer transfer mechanism 18 outside the film deposition apparatus 1 can enter the vacuum chamber 11 through the transfer opening 16. The wafer transfer mechanism 18 transfers the wafer W to the concave portion 21 facing the transfer opening 16. Although the depiction is omitted, lifting pins are provided to transfer the wafer W between the wafer transfer mechanism 18 and the concave portion 21 located at a position facing the transfer opening 16. The lifting pins are configured to be able to protrude from a lower side of the bottom part of the vacuum chamber 11 to a position above the turntable 2 through the through holes 22 of the concave portion 21.

As illustrated in FIGS. 2 and 3, above the turntable 2, a first gas shower head 41, a separation gas nozzle 31, a second gas shower head 42 and a separation gas nozzle 32 are arranged in a circumferential direction in this order. The first gas shower head 41 discharges BTBAS (bis(tertiary-butyl-amino)silane) gas, and the second gas shower head 42 discharges O₃ (ozone) gas, respectively. BTBAS gas is thermally decomposed at a temperature of 520 degrees C. or higher under 1 atmospheric pressure. Accordingly, the first gas shower head 41 is configured not to generate the thermal decomposition at a surface of the gas shower head 41 while discharging BTBAS gas. A description is given later of a detailed configuration of the first gas shower head 41 and the second gas shower head 42.

Each of the separation gas nozzles 31 and 32 is formed to have a rod-like shape that extends from an outer periphery toward the center of the turntable 2 and has many discharge holes for discharging N₂ (nitrogen) gas in its lower surface formed along a lengthwise direction thereof. In other words, each of the separation gas nozzles 31 and 32 supplies N₂ gas as a separation gas along a radius of the turntable 2.

The ceiling plate 12 of the vacuum chamber 11 includes two sectorial convex portions 33 protruding downward, and the convex portions 33 are formed at intervals in the circumferential direction. The separation gas nozzles 31 and 32 are provided so as to cut into the convex portions 33 and to divide the convex portions 33 into two in the circumferential direction, respectively. Areas under the convex portions 33 are formed as separation areas D to which the separation gas is supplied.

A ring plate 24 is provided at the bottom of the vacuum chamber 11 and outside the turntable 2 in the radius direction thereof, and the ring plate 24 has two exhaust openings 25 opened at intervals in a circumferential direction thereof. An end of an exhaust pipe 26 is connected to each of the exhaust openings 25. The other end of each of the exhaust pipes 26 joins together and is connected to an exhaust mechanism 28 constituted of a vacuum pump by way of an exhaust gas amount adjustment mechanism 27. The exhaust gas amount adjustment mechanism 27 adjusts an amount of exhaust gas from each of the exhaust openings 25, thereby adjusting a pressure inside the vacuum chamber 11.

The vacuum chamber 11 is configured to be able to supply N₂ gas into a space above a central area C of the turntable 2 through a gas supply pipe 30. N₂ gas supplied into the space above the central area C flows outward of the turntable 2 in the radius direction thereof as a purge gas by way of a flow passage under a ring-shaped protrusion portion 34 protruding downward in a ring shape in the central part of the ceiling plate 12. A lower surface of the ring-shaped protrusion portion 34 is configured to be continuously connected to lower surfaces of the convex portions 33 that form the separation areas D.

As illustrated in FIG. 1, a supply pipe 23 is provided for supplying N₂ gas as a purge gas to a location under the turntable 2. A depression part is formed that constitutes a heater accommodation space 36 along the rotational direction of the turntable 2 in the bottom surface of the chamber body 13 under the turntable 2, and heaters 37 that form a plurality of heating units are provided in the heater accommodation space 36 in a concentric fashion when seen in a plan view. As illustrated in FIG. 1, a plate 38 is provided that forms the heater accommodation space 36 by covering the depression part from above. Radiation heat from the heaters 37 heats the plate 38, and the radiation heat from the plate 38 heats the turntable 2, thereby heating the wafers W. As illustrated in FIG. 1, a supply pipe 20 for supplying N₂ gas as the purge gas to the heater accommodation space 36 during the film deposition process is provided.

As illustrated in FIGS. 2 and 3, a rod-like cleaning gas nozzle 39 is provided so as to penetrate the side wall of the vacuum chamber 11 from the outside of the vacuum chamber 11 and to enter the inside thereof, and is arranged between the first gas shower head 41 and the convex portion 33 adjacent to the first gas shower head. The cleaning gas nozzle 39 that constitutes a cleaning gas supply part discharges a clean gas to the surface of the turntable 2 from the tip thereof. The cleaning gas is constituted of a fluorine-containing gas (fluorine-containing compound gas or a gas containing fluorine gas) including ClF₃ (chlorine trifluoride), NF₃ (nitrogen trifluoride) or the like. The discharged cleaning gas is supplied from the periphery to the central part of the turntable 2, and removes silicon oxide deposited on the turntable 2.

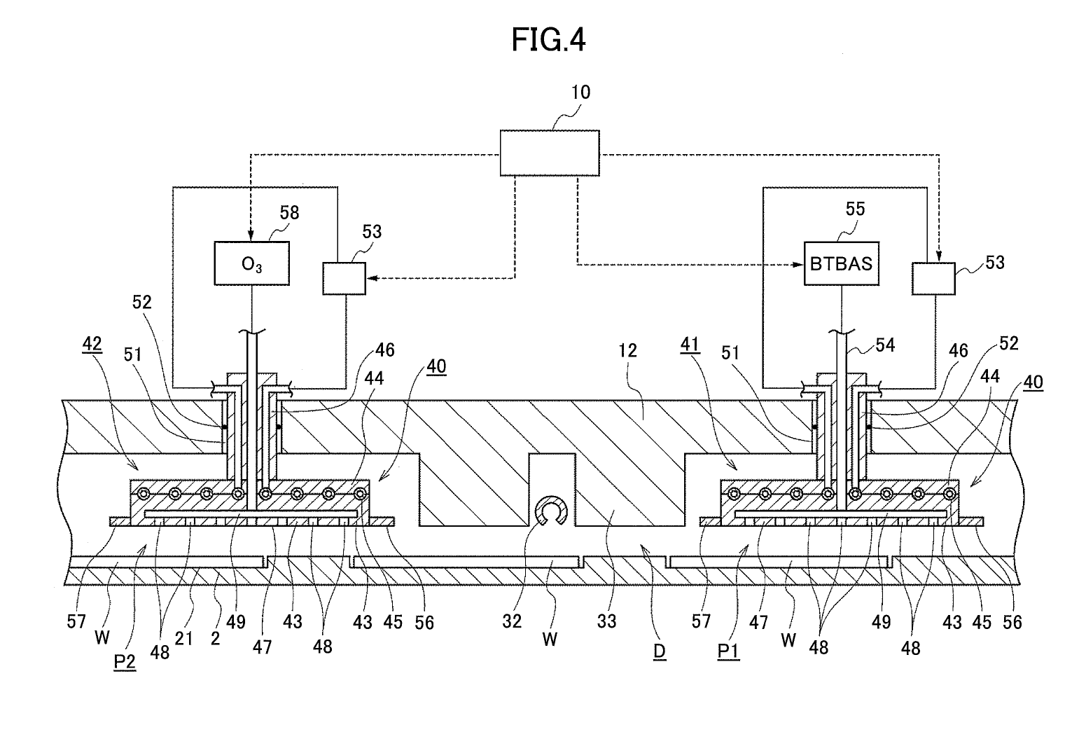

Next, a description is given below of a configuration of the gas shower heads 41 and 42. Each of the gas shower heads 41 and 42 is provided apart from the convex portions 33 in the rotational direction, and is formed into a sectorial shape that spreads from the central side toward the peripheral side of the turntable 2. Because the first gas shower head 41 and the second gas shower head 42 are configured similarly to each other, a description is given of only the first gas shower head 41 as a representative of the gas shower heads 41 and 42, with also reference to FIG. 4 in addition to FIGS. 2 and 3. FIG. 4 illustrates a vertical cross section cut along the rotational direction of the turntable 2 including each portion inside the vacuum chamber 11.

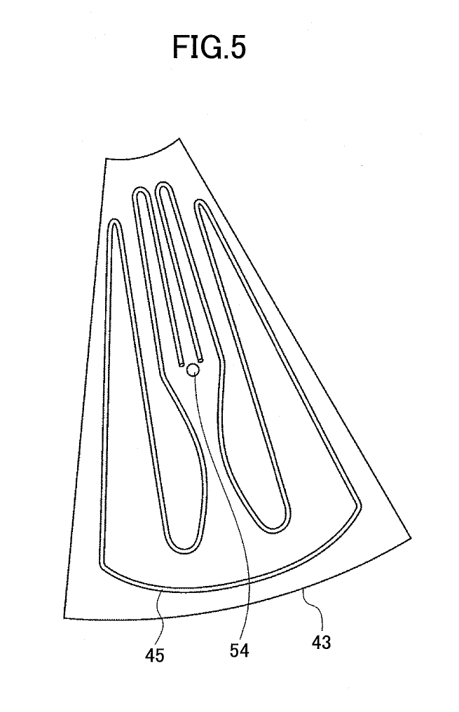

The first gas shower head 41 is constituted of a main body 40, a pipe arrangement 45 and a support 46 having a cylindrical shape. The main body 40 is formed into a flattened sectorial shape, and is constituted of a lower member 43 and an upper member 44. In this example, the lower member 43 and the upper member 44 are bonded by welding, but may be joined together by using a member such as a screw instead of welding. The pipe arrangement 45 is drawn around between the lower member 43 and the upper member 44. Although FIG. 5 illustrates an example of a layout of the pipe arrangement 45 on the lower member 43, but as described later, the pipe arrangement 45 can be arranged in any layout as long as the pipe arrangement 45 can cool the surface of the gas shower head 41 by a coolant flowing through the pipe arrangement 45.

A description is given below with reference to FIG. 4 again. A lower end of a support 46 for supporting the main body 40 is connected to an upper surface of the main body 40, and an upper end of the support 46 is drawn outward through an opening 51 provided in the ceiling plate 12 of the vacuum chamber 11. As illustrated in FIG. 4, a ring member 52 is provided to seal a gap between the opening 51 and the support 46. Each of an upstream side and a downstream side of the pipe arrangement 45 is drawn to the outside of the vacuum chamber 11 through the support 46, and is connected to a coolant supply mechanism 53 that constitutes a chiller.

The coolant supply mechanism 53 that constitutes a cooling mechanism with the pipe arrangement 45 supplies, for example, perfluoropolyether (Galden (Trademark)) to the upstream side of the pipe arrangement 45. Then, the coolant supply mechanism 53 cools the coolant supplied from the downstream side of the pipe arrangement 45 whose temperature has increased while flowing through the inside of the first gas shower head 41 and supplies the cooled coolant to the upstream side of the pipe arrangement 45 again. In other words, the coolant supply mechanism 53 and the pipe arrangement 45 constitute a circuit of the coolant.

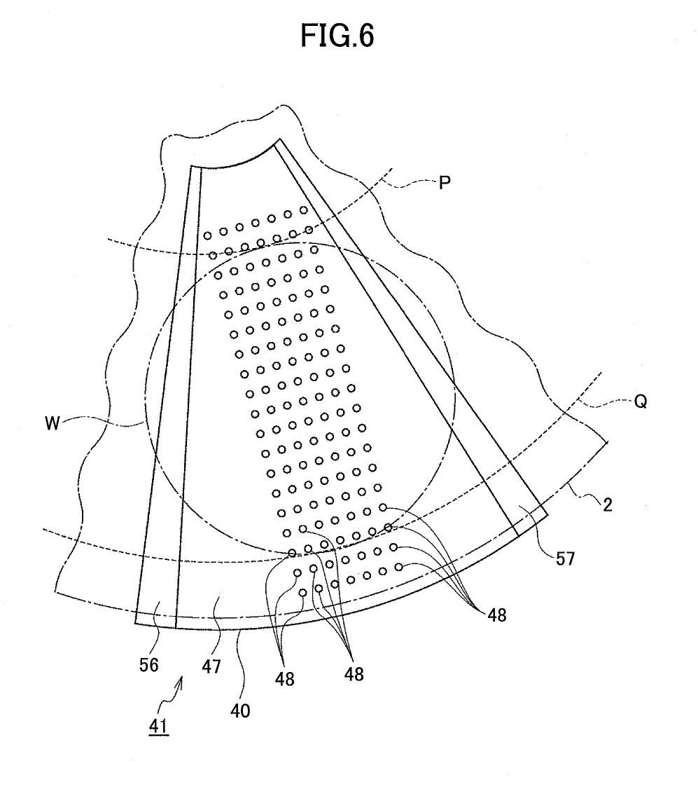

A lower surface of the main body 40 is configured to be an opposed surface 47 having a sectorial shape facing a surface of the turntable 2 and a surface of the wafer W, and FIG. 6 illustrates the opposed surface 47. Many gas discharge holes 48 are opened in the opposed surface 47. The gas discharge holes 48 are formed to form a straight line heading from the rotational center side toward the peripheral side of the turntable 2. FIG. 6 illustrates the wafer W by an alternate long and short dash line passing under the opposed surface 47 by rotating the turntable 2. With respect to the rotating wafer W, a locus of an end on the rotational center side of the turntable 2 is illustrated by a dotted line P, and a locus of an end on the peripheral side of the turntable 2 is illustrated by a dotted line Q. Gas discharge holes 48 formed closest to the rotational center of the turntable 2 in each row are provided closer to the rotational center than the locus P. The gas discharge holes 48 formed closest to the outer circumference of the turntable 2 in each row are provided closer to the outer circumference than the locus Q. Such a structure enables a single line of the gas discharge holes 48 to supply a gas to the entire surface of the rotating wafer W.

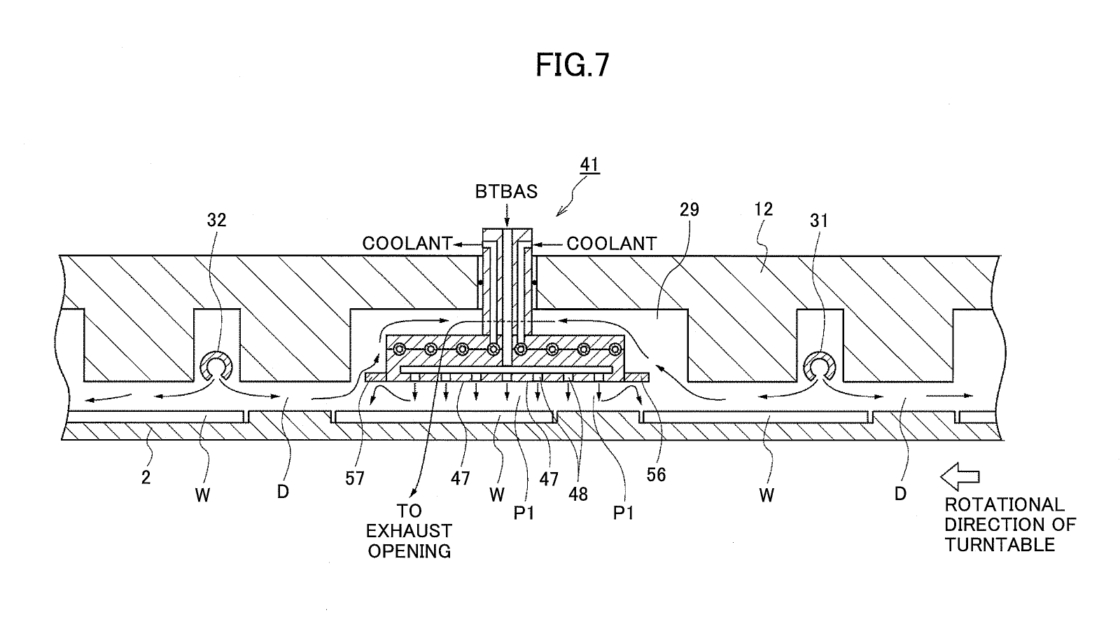

As illustrated in FIG. 7, seven rows of the gas discharge holes 48 heading from the rotational center side toward the peripheral side are formed in the gas shower head 41. As discussed above, a plurality of rows of the gas discharge holes 48 is provided because the duration of contact between BTBAS gas and the wafer W can be made longer than the case of providing only a single row of the gas discharge holes 48, while the wafer W is passing under the gas shower head 41. In other words, the structure intends to enhance the adsorption efficiency of BTBAS gas on the wafer W for each rotation of the turntable 2 and to increase the film deposition speed.

In the meantime, when a test for examining a film deposition condition on a wafer W was performed by changing a number of rows in the gas shower head 41, BTBAS gas did not sufficiently adsorb on the wafer W in the event that only 1 through 4 of the rows were provided. In contrast, it was recognized that the adsorption efficiency could be enhanced as the number of rows increased, according to the test. Hence, providing five or more of the rows is effective. However, if the number of rows is too many, when supply of BTBAS gas to the gas shower head 41 is constant, BTBAS gas cannot be discharged at a sufficient flow rate from each of the rows, which may deteriorate the film quality. Increasing the supply of BTBAS gas to the gas shower head 41 causes an increase in operational cost of the film deposition apparatus, and requires a design change of the film deposition apparatus, which is disadvantageous. In this manner, in terms of suppressing the deterioration of film quality, and from a result of the test, setting the number of rows at 12 or less is thought to be effective.

A description is continued with reference to FIG. 4 again. The lower member 43 includes a flattened gas diffusion space 49, and an upper part of each of the gas discharge holes 48 is in communication with the gas diffusion space 49. A downstream end of a gas supply passage 54 is connected to an upper part of the gas diffusion space 49. An upstream end of the gas supply passage 54 is formed so as to penetrate through the support 46 upward, and is connected to a supply source 55 of BTBAS gas provided outside the vacuum chamber 11.

Current plates 56 and 57 are provided so as to protrude toward the upstream side and the downstream side in the rotational direction of the turntable 2 from the lower ends of the lower member 43, and the current plates 56 and 57 are formed into a sectorial shape spreading from the rotational center side toward the outside when seen in a plan view. The current plates 56 and 57 serve to suppress BTBAS gas discharged from the gas discharge holes 48 to the wafer W from diffusing so as to flow up toward the outside and upside of the gas shower head 41 and to prevent a concentration of BTBAS gas under the shower head 41 from decreasing. An area under the opposed surface 47 and the current plates 56 and 57 is made a first process area P1 where the wafer W is processed by supplying BTBAS gas. The current plates 56 and 57 are configured be opposed parts with the opposed surface that face a passing area of the wafer W rotated by the rotation of turntable 2.

Moreover, a circulation space 29 for a gas is formed between an upper surface of the upper member 44 and a ceiling surface constituted of the ceiling plate 12 of the vacuum chamber 11. FIG. 7 is also referred to, to explain the circulation space 29. In FIG. 7, gas flows around the first shower head 41 during the film deposition process are illustrated by arrows. The separation gas discharged from the separation gas nozzle 31 flows from the upstream side in the rotational direction of the turntable 2 toward the first gas shower head 41. The separation gas discharged from the separation gas nozzle 32 flows from the downstream side in the rotational direction of the turntable 2 toward the first shower head 41.

Thus, each separation gas flowing from the upstream side and the downstream side in the rotational direction is likely to flow to the circulation space 29 having a low pressure than to the first process area P1 having a high pressure caused by the discharged first reaction gas. Then, the separation gas having flown to the circulation space 29 flows therefrom to the outside of the turntable 2 and is evacuated from the exhaust opening 25. In other words, by providing the circulation space 29, an inflow of the separation gas to the first process area P1 is suppressed. This prevents BTBAS gas in the first process area P1 from decreasing in concentration, and can certainly prevent the decrease in adsorption efficiency of BTBAS gas on the wafers W. The current plates 56 and 57 serve to cause the separation gases flowing toward the gas shower head 41 from the upstream side and the downstream side in the rotational direction to flow above the current plates 56 and 57 and to guide the separation gases to the circulation space 29. In other words, the current plates 56 and 57 can certainly prevent the decrease in adsorption efficiency. However, configuring the gas shower head 41 without the current plates 56 and 57 is also possible.

In the meantime, in order to perform the film deposition, a temperature on one surface side of the turntable 2 is heated up to 600 degrees C. or higher by the heaters 37. The surface of the first shower head 41 is heated by receiving the irradiation heat from the turntable 2 heated in this manner. Although BTBAS gas contacts the opposed surface 47 of the first shower head 41 and the lower surfaces of the current plates 56 and 57 when discharged, in the event that the temperature of the opposed surface 47 and the lower surfaces of the current plates 56 and 57 become too high, BTBAS decomposes as described in the “Background of the Invention” section, and cannot deposit a film on the wafer W. Therefore, the coolant supply mechanism 53 supplies the coolant adjusted to a predetermined temperature to the pipe arrangement 45 so as not to generate such decomposition during the film deposition process. More specifically, during the film deposition process, the coolant is supplied so that a temperature of a location having the highest temperature of the opposed surface 47 and the current plates 56 and 57 is lower than the decomposition temperature of BTBAS gas that is the first process gas. When the current plates 56 and 57 are not provided, the coolant is supplied so that the temperature of the location having the highest temperature of the opposed surface 47 is lower than the decomposition temperature.

In order to perform the refrigeration by such a coolant, the main body 40 of the gas shower head 41, the pipe arrangement 45, the support 46 and the current plates 56 and 57 are made of a material having high conductivity. The material having the high conductivity is, for example, metal, and more specifically, for example, aluminum.

Moreover, in the film deposition apparatus 1, the cleaning treatment by using the cleaning gas is performed after the film deposition process, as discussed above. During the cleaning treatment, if the surface temperature of the gas shower head 41 is high, the cleaning gas etches the surface of the gas shower head 41 of aluminum, and particles are generated. When the particles are generated, the particles are liable to remain in the vacuum chamber 11 during the cleaning treatment, and to attach to the wafer W during the film deposition process. To prevent this, in the cleaning treatment, the coolant is supplied to the pipe arrangement 45 so that a temperature of a location having the highest temperature among locations contacting the cleaning gas at the surface of gas shower head 41 is made equal to or lower than 70 degrees C. The locations contacting the cleaning gas are locations that face a space in the vacuum chamber 11, and more specifically, are surfaces of the main body 40, the current plates 56 and 57, and the support 46 below the ring member 52.

In this manner, the locations that need the temperature control in the cleaning treatment include the lower surfaces of the opposed surface 47 and the current plates 56 and 57. In this operational example of the film deposition apparatus 1, in order to quickly switch between the film deposition and the cleaning treatment, the temperature of the lower surfaces of the opposed surface 47 and the current plates 56 and 57 is adjusted so as to be equal to or lower than 70 degrees C. even during the film deposition process by using the coolant.

A description is also given below of the second gas shower head 42. The second gas shower head 42 includes a supply source 58 of O₃ gas as a gas supply source. Each drawing expresses an area under the opposed surface 47 and the current plates 56 and 57 where the O₃ gas is supplied, as a second process area P2.

The film deposition apparatus 1 includes a control unit 10 configured to control the operation of the entire apparatus and constituted of a computer. The control unit 10 stores a program for executing the film deposition process and the cleaning treatment as described later. The control unit 10 sends a control signal to each part of the film deposition 1 by running the program.

More specifically, the control unit 10 controls each operation such as the supply and stop of the reaction gases from the gas supply sources 55 and 58 to the gas shower head 41 and 42, the supply and stop of the separation gas from a gas supply source not illustrated in the drawings to the separation gas nozzles 31 and 32 and the central area C, the control of the rotational speed of the turntable 2 by the rotary drive mechanism 15 by running the program. Moreover, the control unit 10 also controls each operation such as the supply and stop of the electric power to the heaters 37, the adjustment of the amount of exhaust gas from each of the vacuum exhaust openings 25 by the exhaust gas amount adjustment mechanism 27, the adjustment of a supply amount of the coolant by the coolant supply mechanism 53 and the temperature adjustment of the coolant by running the program. In the program, a group of steps is organized to control such an operation and to execute each process described later. The program is installed into the control unit 10 from a storage medium such as a hard disk, a compact disc, a magnetic optical disk, a memory card and a flexible disk and the like.

A description is given below of the film deposition process on the wafer W by the film deposition apparatus 1 and the cleaning treatment. One surface side (the upper surface side) of the turntable 2 is heated up to 600 degrees C. or higher, for example, 720 degrees C., by the heaters 37. On the other hand, the coolant circulates the circuit constituted of the coolant supply mechanism 53 and the pipe arrangement 45, and the surface temperature of the first gas shower head 41 and the second gas shower head 42 in the vacuum chamber 11 is controlled to become 70 degrees C. or lower. More specifically, the temperature of the surfaces of the main body 40 constituting each of the gas shower heads 41 and 42, the current plates 56 and 57 and the support 46 are adjusted to 70 degrees C. or lower.

In such a state, when the gate valve 17 is opened and the wafer transfer mechanism 18 holding the wafer W goes into the vacuum chamber 11 from the transfer opening 16, lifting pins not illustrated in the drawings move up from the through holes 22 of the concave portion 21 located at a position facing the transfer opening 16 to push up the wafer W, and the wafer W is transferred to the concave portion 21 from the wafer transfer mechanism 18. The wafer W placed on the concave portion 21 is heated to 720 degrees C. by heat transfer from the turntable 2. The wafers W are sequentially transferred to the other concave portions 21 by intermittent rotation of the turntable 2 and the above-described operations of the lifting pins and the transfer mechanism 18. After the wafers W are placed on all of the five concave portions 21, the gate valve 17 is closed, and the turntable 2 continuously rotates.

The separation gas nozzles 31 and 32 discharge N₂ gas, which is the separation gas, at a predetermined flow rate. Furthermore, N₂ gas that is a purge gas is supplied to the central area C at a predetermined flow rate, and the purge gas is discharged from the central area C so as to spread toward the periphery of the turntable 2. While discharging N₂ gas in the manner, BTBAS gas and O₃ gas are discharged from the first gas shower head 41 and the second gas shower head 42, respectively, and a film deposition process starts. While discharging each of the gases, by evacuating the vacuum chamber 11, the inside of the vacuum chamber 11 becomes a vacuum atmosphere, for example, of 1 Pa to 1000 Pa.

The wafers W pass through the first process area P1 under the first gas shower head 41 and the second process area under the second gas shower head 42 alternately. BTBAS gas adsorbs on the wafers W, and then O₃ gas adsorbs on the wafers W, and a thermal decomposition occurs on surfaces of the wafers W. Next, O₃ gas adsorbs on the wafers W, by which a decomposed matter is oxidized and one or more molecular layers of silicon oxide are deposited on the wafers W. In this manner, the molecular layers of a silicon oxide film are sequentially deposited in a layer-by-layer manner and a film thickness of the silicon oxide film grows gradually thicker.

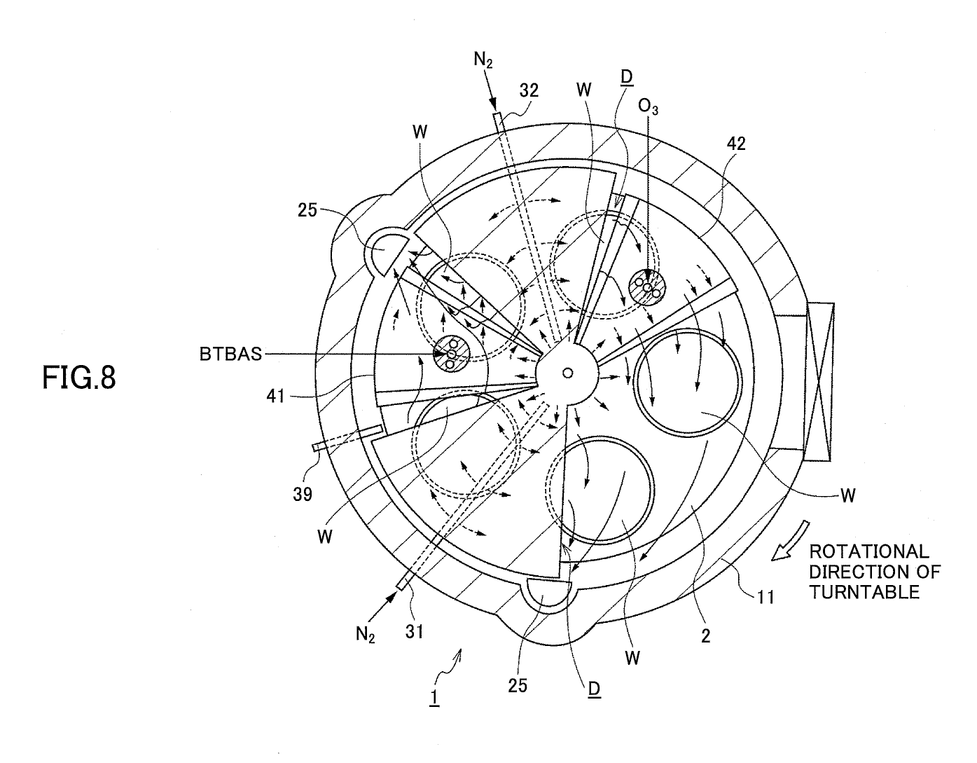

FIG. 8 illustrates flows of the gases inside the vacuum chamber 11 by arrows. N₂ gas supplied from the separation gas nozzles 31 and 32 to the separation areas D expands in the separation areas D in a circumferential direction, and prevents BTBAS gas and O₃ gas from mixing with each other above the turntable 2. Moreover, N₂ gas supplied to the central area C expands outward in a radius direction of the turntable 2, and prevents BTBAS gas and O₃ gas from mixing with each other in the central area C. Furthermore, in the film deposition apparatus 1, N₂ gas is supplied to the heater accommodation space 36 and the back surface side of the turntable 2 from the supply pipes 20 and 23 (see FIG. 1), thereby purging the reaction gases. FIG. 7 discussed above illustrates a vertical cross-sectional side view of the vacuum chamber 11 when each of the gases is supplied into the vacuum chamber 11 in this manner.

Because the surface of the first shower head 41 is adjusted to a temperature equal to or lower than 70 degrees C. that is lower than a decomposition temperature of BTBAS gas under the vacuum atmosphere, the discharged BTBAS gas is supplied to the wafer without being decomposed by heat under the opposed surface 47 and the lower surface of the current plates 56 and 57. As discussed above, because BTBAS gas is supplied to a relatively large area above the turntable 2 by the gas discharge holes 48 of the first gas shower head 48 opened in seven rows, a contact time between BTBAS gas and the wafers W is long while the wafers W pass through the first process area P1, and an adsorption of the decomposed BTBAS gas advances efficiently. In addition, because the second shower head 42 also supplies O₃ gas to a relatively large area similarly to the first gas shower head 41, the oxidation of the decomposed matter also advances efficiently, and growth of the silicon oxide film quickly advances. Then, the silicon oxide film is annealed by being heated at 720 degrees C. during the growth, thereby solving disarray of a molecular arrangement.

When the silicon oxide film having a predetermined film thickness is deposited by a predetermined number of times of rotation of the turntable 2, the supply of each of the gases and the rotation of the turntable 2 are stopped, and the film deposition process finishes. Even after finishing the film deposition process, the surface of the turntable 2 is maintained at, for example, 720 degrees C. or higher while the surface of each of the gas shower heads 41 and 42 in the vacuum chamber 11 is maintained at 70 degrees C. or lower. The gate valve 17 is opened, and the wafers W are sequentially transferred to the wafer transfer mechanism 18 and carried out of the vacuum chamber 11 by the intermittent rotation of the turntable 2 and the elevating and lowering operation. After all of the wafers W are carried out of the vacuum chamber 11, the gate valve 17 is closed.

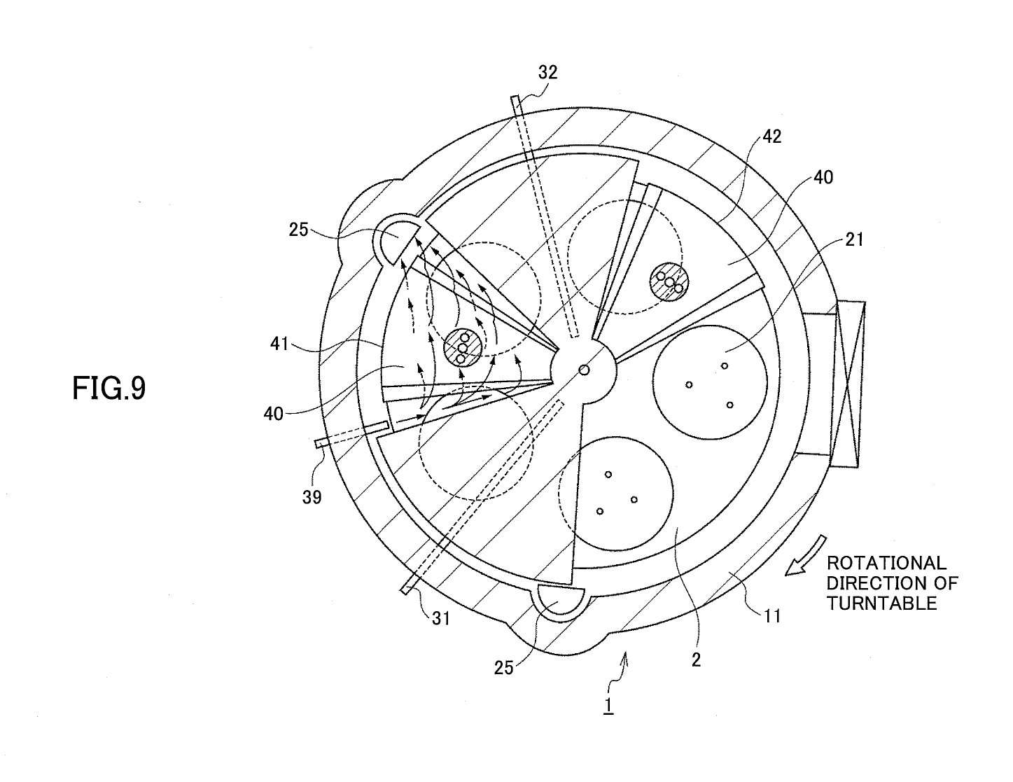

After that, the turntable 2 continuously rotates again, and a cleaning treatment starts by supplying a cleaning gas from the cleaning gas nozzle 39. The pressure inside the vacuum chamber 11 becomes, for example, 1 Pa to 1000 Pa. FIG. 9, as well as FIG. 8, illustrates flows of a gas inside the vacuum chamber 11 by arrows. The cleaning gas supplied to the turntable 2 decomposes the silicon oxide film deposited on the turntable 2, is suctioned toward the exhaust opening 25 with the decomposed matter, and passes both on the lower side and the upper side of the first shower head 41. As discussed above, because the surface of the first gas shower head 41 is cooled, the cleaning gas flows into the exhaust opening 25 without etching the first shower head 41, together with the decomposed matter, and is removed. After the turntable 2 rotates a predetermined number of times, the turntable 2 stops rotating while the supply of the cleaning gas stops, and the cleaning treatment finishes.

After finishing the cleaning treatment, the wafers W are transferred into the vacuum chamber 11, and the above-mentioned film deposition process is performed again. Because the surface temperature of the turntable 2 is maintained at 720 degrees C. or higher even during the cleaning treatment, the wafers W transferred into the vacuum chamber 11 and placed on the concave portions 21 are promptly heated. Accordingly, a period of time can be shortened that is required to set all of the wafers W at a setting temperature by heating after finishing placing the wafers W on all of the concave portions 21. Hence, because the film deposition process can be started quickly again, the throughput can be improved. In the meantime, although the above description has given an example of operating the film deposition apparatus 1 in a way of performing the cleaning treatment after performing the film deposition process once, and performing the film deposition process again, the film deposition apparatus 1 may be operated in a way of performing the cleaning treatment once, and then performing the film deposition process again a plurality of number of times.

According to the film deposition apparatus 1, the first gas shower head 41 for supplying BTBAS gas is provided, and the surface of the first gas shower head 41 is cooled by the coolant supplied from the coolant supply mechanism 53. By adopting such a configuration, because BTBAS gas can be supplied to a relatively large area, a contact time between the wafers W and BTBAS gas while the turntable 2 rotates once can be made longer. Accordingly, a film deposition speed of the silicon oxide film on the wafers W can be improved. Moreover, because the discharged BTBAS gas can heat the wafers W up to a relatively high temperature while preventing the discharged BTBAS gas from decomposing, the film quality of the silicon oxide film can be enhanced.

In the above example, although the temperature of the surface of the first gas shower head 41 inside the vacuum chamber 11 is adjusted to 70 degrees C. or lower during both of the film deposition process and the cleaning treatment, as discussed above, the temperature of the surface of the first gas shower head 41 may be adjusted to any temperature as long as BTBAS gas does not decompose, and therefore, the temperature may be adjusted to a temperature higher than 70 degrees C. Therefore, during the film deposition process, the operation of the coolant supply mechanism 53 may be controlled so that the surface temperature of the first gas shower head 41 becomes higher than that during the cleaning treatment. More specifically, the surface temperature may be controlled to vary between during the film deposition process and during the cleaning treatment by more increasing the temperature of the coolant supplied to the first gas shower head 41 or decreasing a flow rate of the coolant more during the film deposition process than during the cleaning treatment. By performing the control in this manner, the operational cost of the film deposition apparatus can be reduced.

In addition, in order to perform the cleaning treatment, the temperature of the turntable 2 may be set at 600 degrees C. or lower. Therefore, by decreasing an output of the heaters 37 more during the cleaning treatment than during the film deposition process, the surface temperature of the first gas shower head 41 during the cleaning treatment may be controlled to become 70 degrees C. or lower.

In the meanwhile, in the above example, although O₃ gas is also supplied by using the gas shower head 42 in order to supply O₃ gas to the relatively large area as well as BTBAS gas, because O₃ gas has a decomposition temperature higher than that of BTBAS gas, O₃ gas may be supplied into the vacuum chamber 11 by using a gas nozzle similar to the separation gas nozzles 31 and 32.

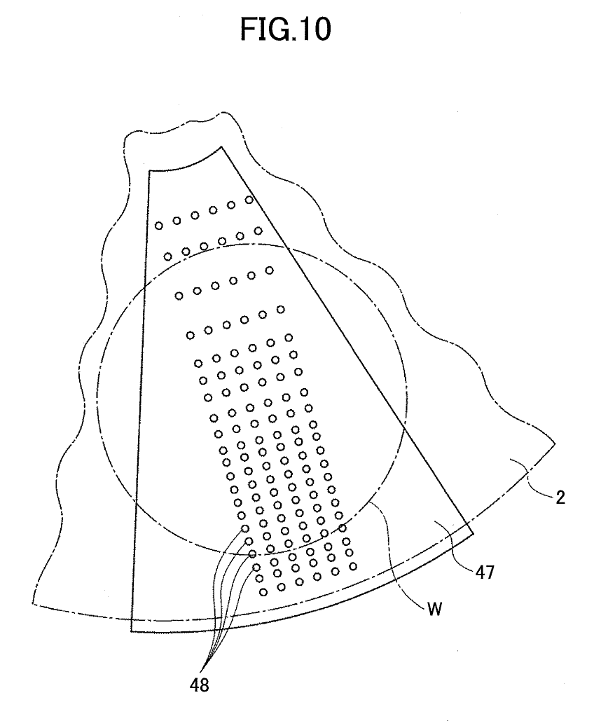

The layout of the gas discharge holes 48 in the opposed surface 47 of the first gas shower head 41 is not limited to the above-mentioned examples. In an example illustrated in FIG. 10, a distance of adjacent gas discharge holes differs on the central side and the peripheral side in the rotational direction of the turntable 2 in a single row. More specifically, on the rotational center side of the turntable 2, the distance of the gas discharge holes 48 adjacent to each other is a single row is relatively large. In contrast, on the peripheral side of the turntable 2, the distance of the gas discharge holes adjacent to each other in a single row is relatively narrow. Because the length of the circumference of the turntable 2 increases with decreasing distance from the outer edge of the turntable 2, by forming the gas discharge holes 48 in this manner, the gas discharge amount on the peripheral side is controlled to become greater on the peripheral side than on the rotational center side. By forming the gas discharge holes 48 in this manner, the uniformity of the film thickness distribution of the silicon oxide film within a surface of a wafer W can be enhanced. Here, in the example of FIG. 10, a number of rows of the gas discharge holes 48 heading to the peripheral side of the turntable 2 from the rotational center is made six, and the current plate 56 and 57 are not provided.

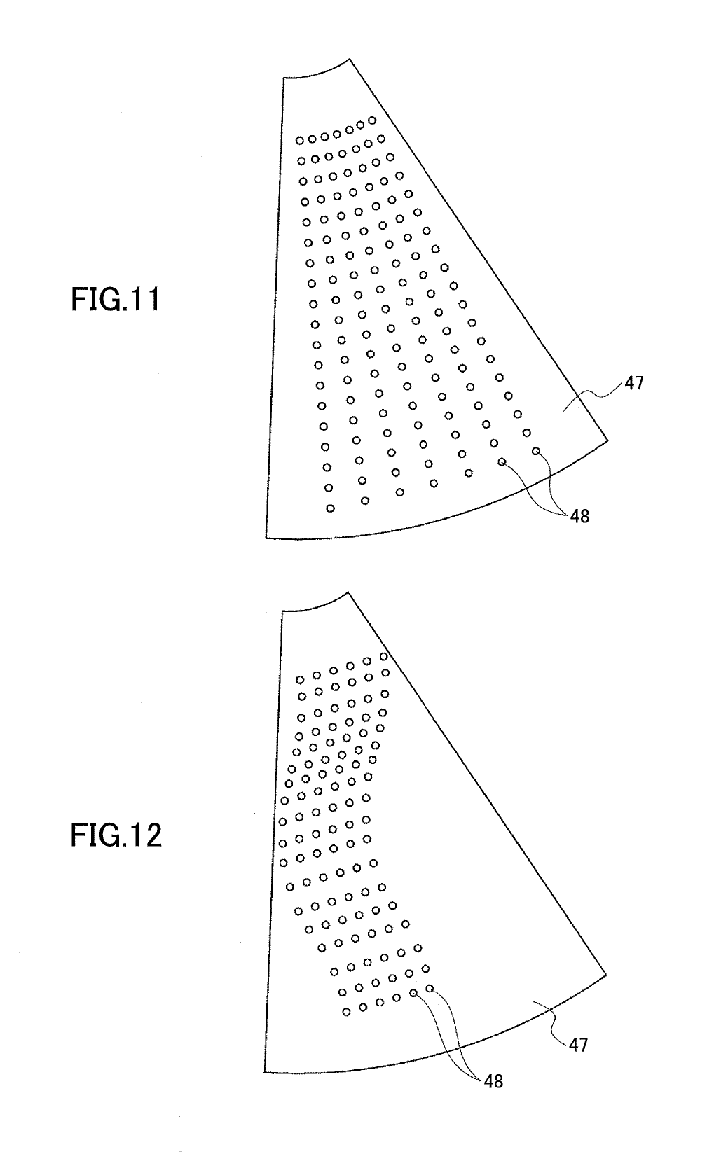

Moreover, in the examples illustrated in FIGS. 6 and 10, although the rows of the gas discharge holes 48 are provided in parallel to each other, the configuration is not limited to the examples. As illustrated in FIG. 11, rows may be formed to increase a distance from the adjacent row with decreasing distance from the outer edge of the turntable 2. Furthermore, as illustrated in FIG. 12, each of the rows is not limited to a straight line, but may be formed into a curved line. The above-mentioned layouts of the gas discharge holes 48 may be combined with each other.

Instead of BTBAS gas of the Si (silicon)-based gas, Hf (hafnium)-based gas, Sr (strontium)-based gas, Al (aluminum)-based gas, Zr (zirconium)-based gas and the like may be used as the first process gas (the source gas). In other words, the film deposition apparatus 1 can be applied to the case of depositing a film composed mostly of Hf, Sr, Al, Zr. Its application is not limited to a film composed mostly of Si.

The embodiments of the present invention can be applied to the case of depositing a film by CVD (Chemical Vapor Deposition). More specifically, for example, to do this, the gas shower head 41 is configured to include two independent gas flow passages separated from each other so that two kinds of gases passing through each of two of the gas flow passages is discharged from the opposed surface 47 without being mixed with each other within the gas shower head 41. Then, the discharged two kinds of gases may be deposited on the wafer W by chemically reacting with each other on the wafer W by heat of the wafer W. Furthermore, the apparatus may be configured to include only a single gas shower head and to deposit a film by discharging a single kind of gas from the gas shower head by the CVD using the gas.

With respect to each of the gas shower heads 41 and 42, in the above examples, although the support 46 is configured to extend to the location above the vacuum chamber 11 and to supply the gas to the main body 40 of each of the gas shower heads 41 and 42 from above, the configuration is not limited to such a configuration. For example, the support 46 may be configured to extend so as to penetrate through the side wall of the vacuum chamber 11 from the main body 40 to the outside thereof and to supply the gas from the lateral outside to the main body 40. However, by configuring the support 46 so as to extend upward, ensuring a space to allow the support 46 to protrude in the lateral side of the vacuum chamber 11 is not needed. Furthermore, because the pipe arrangement 45 can be drawn around on the upper side of the vacuum chamber 11, a space for drawing the pipe arrangement 45 around is not needed in the lateral side of the vacuum chamber 11. Accordingly, an effect of reducing a footprint of the apparatus can be obtained.

According to the embodiments of the present invention, a gas shower head for supplying a process gas to a substrate placed on a turntable and a cooling mechanism for cooling an opposed part facing a passing area of the substrate in the gas shower head are provided. The configuration enables an area to which the process gas is supplied to increase in the turntable, and a film deposition speed can be improved. In addition, a film quality can be enhanced because the substrate can be processed by being heated up to a relatively high temperature while preventing the process gas from decomposing in the opposed part.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention.

What is claimed is:

1. A film deposition apparatus for obtaining a thin film by supplying a process gas to a substrate, comprising:
a vacuum chamber;
a rotatable turntable provided in the vacuum chamber and having a substrate receiving area provided in a surface therein to receive a substrate thereon;
a heating unit configured to heat the turntable so as to heat the substrate up to 600 degrees C. or higher in order to perform a film deposition process on the substrate;
a process gas supply part configured to supply a process gas having a decomposition temperature equal to or higher than 520 degrees C. under 1 atmospheric pressure or lower, to the substrate;
a gas shower head provided in the process gas supply part and having a plurality of gas discharge holes provided in an opposed part facing a passing area of the substrate placed on the turntable; and
a cooling mechanism provided in the process gas supply part and configured to cool the opposed part in the gas shower head up to a temperature lower than the decomposition temperature of the process gas.

2. The film deposition apparatus as claimed in claim 1, wherein the process gas supply part forms a first process gas supply part to supply a first process gas to the substrate, the first process gas being a source gas causing a source to adsorb on the substrate, and
the apparatus further comprising:
a second process gas supply part to supply a second process gas reactable with the source and the first process gas of the source gas to the substrate and provided apart from the first process gas supply part in a rotational direction of the turntable.

3. The film deposition apparatus as claimed in claim 1, further comprising:
a cleaning gas supply part to supply a cleaning gas of a fluorine-containing gas to the surface of the turntable,
wherein the cooling mechanism is configured to cool the opposed part of the gas shower head up to 70 degrees C. or lower while supplying the cleaning gas.

4. The film deposition apparatus as claimed in claim 3, wherein the heating unit is configured to be able to heat the surface of the turntable up to 600 degrees C. or higher while supplying the cleaning gas.

5. The film deposition apparatus as claimed in claim 1, wherein the cooling mechanism is configured to cool the opposed part of the gas shower head up to 70 degrees C. or lower during the film deposition process.

6. The film deposition apparatus as claimed in claim 1, wherein the gas discharge holes form 6 to 12 lines extending from a central side to a peripheral side of the turntable.

7. The film deposition apparatus as claimed in claim 1, wherein the cooling mechanism includes a flow passage for a coolant provided in the gas shower head.

8. The film deposition apparatus as claimed in claim 1, wherein the process gas is a silicon-containing gas for depositing a film composed mainly of silicon on the substrate.
